(19) United States
(12) Patent Application Publication
(10) Pub. No.: US 2002/0021368 A1
(43) Pub. Date: Feb. 21, 2002

(54) PLL circuit for CRT monitor horizontal drive signal

(76) Inventor: Yoshiyuki Uto, Kanagawa (JP)

Correspondence Address: McGinn & Gibb, PLLC, Suite 200, 8321 Old Courthouse Road, Vienna, VA, 22182-3817, US

(21) Appl. No.: 09/907,917

(22) Filed: Jul. 19, 2001

(30) Foreign Application Priority Data
Jul. 28, 2000 (JP) 228403/2000

(51) Int. Cl. H03L 7/00

(52) U.S. Cl. 348/540

(57) ABSTRACT

A PLL circuit for a CRT monitor horizontal drive signal includes a phase comparator, charge pump, LPF, VCO, frequency divider, and switching circuit. The phase comparator compares the phase of an input horizontal sync signal with that of an internal reference signal and outputs a phase difference signal. The charge pump outputs a charge pump signal in accordance with the phase difference signal. The LPF converts the charge pump signal into a voltage control signal. The oscillation frequency of the VCO is controlled in accordance with the voltage control signal output. The frequency divider frequency-divides an output from the voltage controlled oscillator and outputs a CRT monitor horizontal drive signal phase-locked by a horizontal sync signal. The CRT monitor horizontal drive signal is used to generate the internal reference signal. The switching circuit outputs the phase difference signal to the charge pump during an interval in which a horizontal sync signal is input, and outputs no phase difference signal during an interval in which no horizontal sync signal is input.

### BACKGROUND OF THE INVENTION

The present invention relates to a PLL circuit for a CRT monitor horizontal drive signal, which suppresses variations in the frequency of a horizontal drive (HOUT) signal serving as a reference signal for a drive circuit in a CRT (Cathode Ray Tube) monitor when a horizontal sync (Hsync) signal input to the PLL circuit is abruptly interrupted.

In a conventional PLL circuit for a CRT horizontal drive signal, the phase of an input horizontal sync signal is compared with that of a flyback pulse (FBP) from a drive circuit in a CRT to form a PLL loop, thereby generating an HOUT signal.

More specifically, the above PLL circuit includes a phase comparator for comparing the phase of an input horizontal sync signal with that of an FBP signal, a charge pump for outputting a charge pump signal in accordance with the comparison result obtained by the phase comparator, a low-pass filter (LPF) for outputting a voltage control signal upon reception of this charge pump signal, a VCO (Voltage Controlled Oscillator) whose oscillation frequency changes in accordance with this voltage control signal, a frequency divider for generating an HOUT signal by frequency-dividing a frequency signal from the VCO by 1/n, and a CRT drive circuit for performing horizontal drive operation of the CRT in accordance with an HOUT signal. The phase locking operation of the PLL circuit is executed in accordance with a horizontal sync signal.

FIG. 8 shows the main part of a conventional PLL circuit in detail. A phase comparator 30 is a phase comparator of the frequency/phase comparison type used in general and constituted by NAND circuits 121 to 129 and inverter 715. Reference numeral 701 denotes a horizontal sync signal; 702, an FBP signal; and 707 and 708, UP and DOWN signals representing phase error signals. A charge pump 40 is comprised of constant current sources 743 and 746, a P-channel MOS transistor 744, and an N-channel MOS transistor 745. An LPF 50 is comprised of a resistor 501, capacitors 502 and 503, and an NPN transistor 504.

FIGS. 9A to 9G show a case where the horizontal sync signal 701 is normally input to the PLL circuit having the above arrangement. As shown in FIGS. 9C and 9D, signals representing the phase difference (t23−t22) between the input horizontal sync signal 701 (FIG. 9A) and the FBP signal 702 (FIG. 9B) are extracted as the UP signal 707 and DOWN signal 708 from the phase comparator 30. The extracted UP signal 707 and DOWN signal 708 are sent out as an UP output signal 711 and DOWN output signal 712 to the charge pump 40, as shown in FIGS. 9E and 9F.

The charge pump 40 outputs a charge pump signal in accordance with the UP output signal 711 and DOWN output signal 712. The LPF 50 controls a VCO 60 by using a voltage control signal voltage obtained by converting the charge pump signal. In this case, to keep the control voltage signal output from the LPF 50 at an almost constant voltage, a transistor 504 of the LPF 50, in which the emitter voltage is kept higher than the base voltage, is turned off. With this operation, as shown in FIG. 9G, the output voltage of the LPF 50 undergoes no change.

A capacitor 503 of the LPF 50 filters out high-frequency components, and a capacitor 502 filters out low-frequency components. In general, to stabilize the oscillation of the PLL loop, the capacitance of the capacitor 502 is set to be larger than that of the capacitor 503 by one or two orders of magnitude.

For this reason, the potential on the resistor 501 side of the capacitor 502 drops slower than the output voltage of the LPF 50. If, therefore, the voltage between the base and emitter of the NPN transistor 504 exceeds the potential difference at which the transistor is turned on, charge is supplied from the collector connected to a power supply VDD through the emitter, thus delaying a drop in the output voltage of the LPF 50.

FIGS. 10A to 10G show a case where the horizontal sync signal 701 is interrupted. When the horizontal sync signal input 701 (FIG. 10A) is interrupted, the phase comparator 30 keeps outputting the DOWN signal 708 (FIG. 10D) indicating a phase difference from the moment (t34) at which the FBP signal 702 (FIG. 10B) is input, as shown in FIGS. 10D and 10F. The DOWN signal 708 is inverted into the DOWN output signal 712 (FIG. 10F) to turn on the N-channel MOS transistor 745 of the charge pump 40. With this operation, as shown in FIG. 10G, the output voltage of the LPF 50 abruptly drops. FIGS. 10C and 10E respectively show the UP signal 707 and UP output signal 711.

In this case, the base-emitter ON voltage of the transistor 504 is generally required to be about 0.7 V, and the transistor 504 is kept off until the corresponding potential difference is produced. For this reason, the output voltage of the LPF 50 abruptly drops, and the oscillation frequency of the VCO 60 also decreases, resulting in a decrease in the frequency of an HOUT signal as a frequency-division output. If, however, the frequency of the HOUT signal abruptly decreases, the deflection voltage for an electron beam abruptly rises to destroy the CRT monitor. Countermeasures are therefore required to prevent the frequency of the HOUT signal from an abrupt decrease.

In addition, circuits have been formed on the basis of low power supply voltages because of a recent growing tendency toward power saving. In such a case, therefore, without a potential difference (base-emitter voltage) at which the transistor 504 is turned on, the output voltage of the LPF 50 drops.

### SUMMARY OF THE INVENTION

It is an object of the present invention to provide a PLL circuit for a CRT monitor horizontal drive signal, which prevents the breakdown of a CRT monitor.

In order to achieve the above object, according to the present invention, there is provided a PLL circuit for a CRT monitor horizontal drive signal, comprising phase comparison means for comparing a phase of an input horizontal sync signal with a phase of an internal reference signal and outputting a phase difference signal, charge pump means for outputting a charge pump signal in accordance with the phase difference signal from the phase comparison means, filter means for converting the charge pump signal from the charge pump means into a voltage control signal, a voltage controlled oscillator whose oscillation frequency is controlled in accordance with the voltage control signal output from the filter means, frequency division means for frequency-dividing an output from the voltage controlled oscillator and outputting a CRT monitor horizontal drive signal phase-locked by a horizontal sync signal, the CRT monitor horizontal drive signal being used to generate the internal reference signal, and switching means for outputting the phase difference signal from the phase comparison means to the charge pump means during an interval in which a horizontal sync signal is input, and outputting no phase difference signal from the phase comparison means during an interval in which no horizontal sync signal is input.

### BRIEF DESCRIPTION OF THE DRAWINGS

FIG. 1 is a block diagram showing a PLL loop block used for a CRT monitor horizontal drive signal according to the first embodiment of the present invention;

FIG. 2 is a circuit diagram of a phase comparator, charge pump, and LPF in FIG. 1;

FIG. 3A is a circuit diagram of a phase comparator according to the second embodiment of the present invention;

FIG. 3B is a view showing the input/output logic of a multiplexer in FIG. 3A;

FIG. 4 is a block diagram showing a phase comparator according to the third embodiment of the present invention;

FIG. 5 is a block diagram showing a phase comparator according to the fourth embodiment of the present invention;

FIGS. 6A to 6J are timing charts for explaining the operation of the PLL circuit in FIG. 2 when a horizontal sync signal is in a normal state;

FIGS. 7A to 7J are timing charts for explaining the operation of the PLL circuit in FIG. 2 when a horizontal sync signal is interrupted;

FIG. 8 is a block diagram showing a conventional PLL circuit for a CRT monitor horizontal drive signal;

FIGS. 9A to 9G are timing charts for explaining the operation of the PLL circuit in FIG. 8 when a horizontal sync signal is in a normal state; and

FIGS. 10A to 10G are timing charts for explaining the operation of the PLL circuit in FIG. 8 when a horizontal sync signal is interrupted.

### DESCRIPTION OF THE PREFERRED EMBODIMENTS

The present invention will be described in detail below with reference to the accompanying drawings.

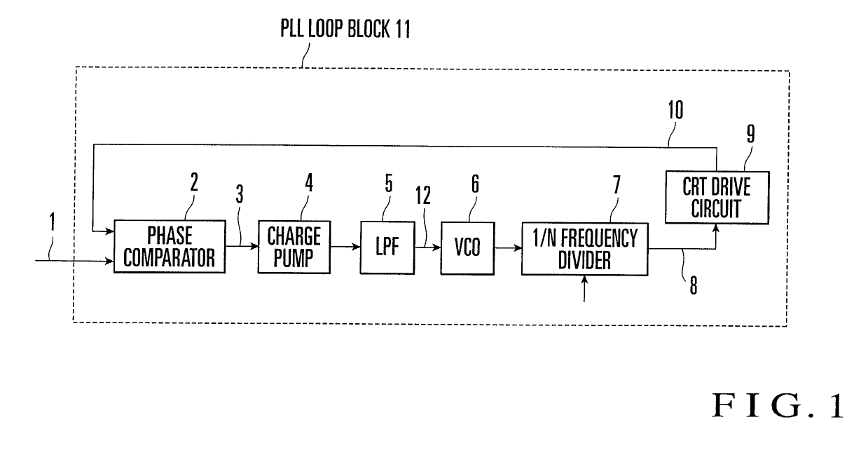

FIG. 1 shows a PLL block according to the first embodiment of the present invention. Referring to FIG. 1, a PLL loop block 11 is comprised of a phase comparator 2 for comparing the phase and frequency of an input horizontal sync signal 1 with those of an FBP signal 10, a current output type charge pump 4 for outputting a charge pump signal (UP/DOWN signal) in accordance with a phase difference signal 3 representing the phase comparison from the phase comparator 2, an LPF 5 formed by a passive lag-lead filter for converting an output from the charge pump 4 into a control voltage signal 12, a VCO 6 whose oscillation frequency changes in accordance with the control voltage signal 12 from the LPF 5, a programmable 1/n frequency divider 7 for which a frequency division ratio n (n is a positive integer) is determined on the basis of the frequency of the input horizontal sync signal 1 and the oscillation frequency of the VCO 6, and a CRT drive circuit 9 for performing the horizontal drive operation of a CRT monitor in accordance with an HOUT signal 8 output from the 1/n frequency divider 7.

The CRT drive circuit 9 performs scan and flyback processing of a horizontal system by generating an electron beam deflection voltage with reference to the HOUT signal 8. At the same time, the CRT drive circuit 9 outputs the FBP signal 10 that is a signal obtained through a coil for generating a deflection voltage and serves as a reference for the display system of the CRT monitor. The phase comparator 2 compares the phase of the FBP signal 10 with that of the horizontal sync signal 1 to phase-lock the HOUT signal 8.

The horizontal sync signal 1 is a signal output from a personal computer, signal generator, or the like. In this case, a synchronous polarity is handled as a positive polarity. If this polarity is a negative polarity, it is only required to add a inversion circuit.

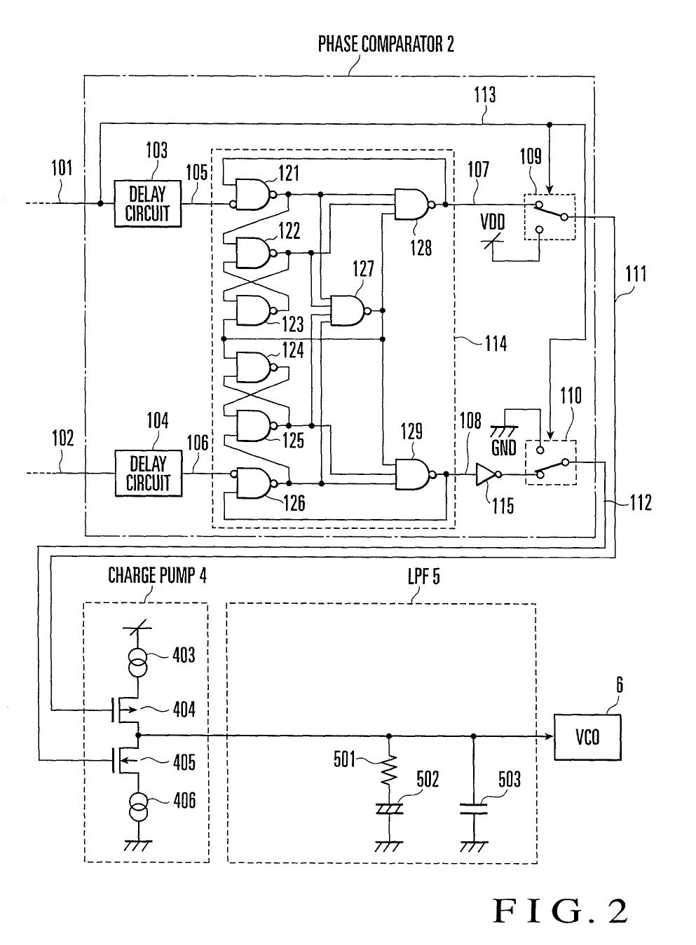

FIG. 2 shows the details of the phase comparator 2, charge pump 4, and LPF 5.

The phase comparator 2 includes a delay circuit 103 for outputting a delayed horizontal sync signal 105 by delaying an input horizontal sync signal 101 (corresponding to the horizontal sync signal 1 in FIG. 1), a delay circuit 104 for outputting a delayed FBP signal 106 by delaying an FBP signal 102 (corresponding to the FBP signal 10 in FIG. 1), and a phase comparison circuit 114 for comparing the frequency and phase of the delayed horizontal sync signal 105 with those of the delayed FBP signal 106 and outputting an UP signal 107 and DOWN signal 108 representing the phase difference. The phase comparison circuit 114 is constituted by NAND circuits 121 to 129.

The phase comparator 2 also includes a switching circuit 109 for outputting the UP signal 107 as an UP output signal during a horizontal sync signal interval and outputting a power supply VDD level so as not to output any comparison result during an interval other than a horizontal sync signal interval, and a switching signal 110 for outputting an inverted signal of the DOWN signal 108 as a DOWN output signal 112 during a horizontal sync signal interval and outputting a GND level so as not to output any comparison result during an interval other than a horizontal sync signal interval. The switching circuits 109 and 110 are constituted by switches, which perform switching operation in accordance with a switching control signal 113 formed by a signal having the same polarity as that of the input horizontal sync signal 101.

The delay circuits 103 and 104 have the same delay amount. The UP signal 107 is output when the phase of the horizontal sync signal 101 leads the phase of the FBP signal 102. The DOWN signal 108 is output when the phase of the FBP signal leads the phase of the horizontal sync signal 101.

The charge pump 4 is formed by cascading a P-channel MOS transistor 404 having a gate to which an output from the switching circuit 109 of the phase comparator 2 is input, an N-channel MOS transistor 405 having a gate to which an output from the switching signal 110 of the phase comparator 2 is input, and current sources 403 and 406. The LPF 5 is comprised of a resistor 501 and capacitors 502 and 503.

The operation of the above PLL circuit will be described next. The PLL circuit shown in FIG. 1 uses an arrangement in which phase locking is performed by using the PLL loop block 11 with reference to the input horizontal sync signal 1. A problem in this case is an abrupt change in the HOUT signal 8.

The CRT drive circuit 9 performs frequency/voltage conversion on the basis of the frequency of the HOUT signal 8, boosts an electron beam deflection voltage to several kV, and performs scan/flyback processing of the horizontal system. At this time, if the frequency of the HOUT signal 8 abruptly decreases, the deflection voltage abruptly rises, resulting in the breakdown of the CRT monitor. The frequency of the HOUT signal 8 abruptly decreases when the horizontal sync signal 1 as a reference signal for the PLL loop block 11 is interrupted.

When the reference signal for the PLL loop block 11 is interrupted, the phase comparator 2 determines a frequency of 0 Hz. As a consequence, the oscillation frequency of the VCO 6 is decreased to a limit, resulting in the breakdown of the CRT. The horizontal sync signal 1 is interrupted when, for example, the capable that connects the personal computer to the CRT monitor is disconnected.

In a CRT monitor system, a microcomputer generally monitors the presence/absence of a horizontal sync signal. The microcomputer spends time to perform determination and inform the determination result. If, therefore, the horizontal sync signal 1 is abruptly interrupted, variations in the HOUT signal 8 cannot be suppressed by using the microcomputer. For this reason, countermeasures against this phenomenon must be taken in the PLL loop for generating the HOUT signal 8.

The present invention includes the switching circuits 109 and 110 for outputting UP/DOWN output signals 111 and 112 only during a horizontal sync signal interval to suppress a change in the frequency of the HOUT signal 8 even if the horizontal sync signal 1 is abruptly interrupted.

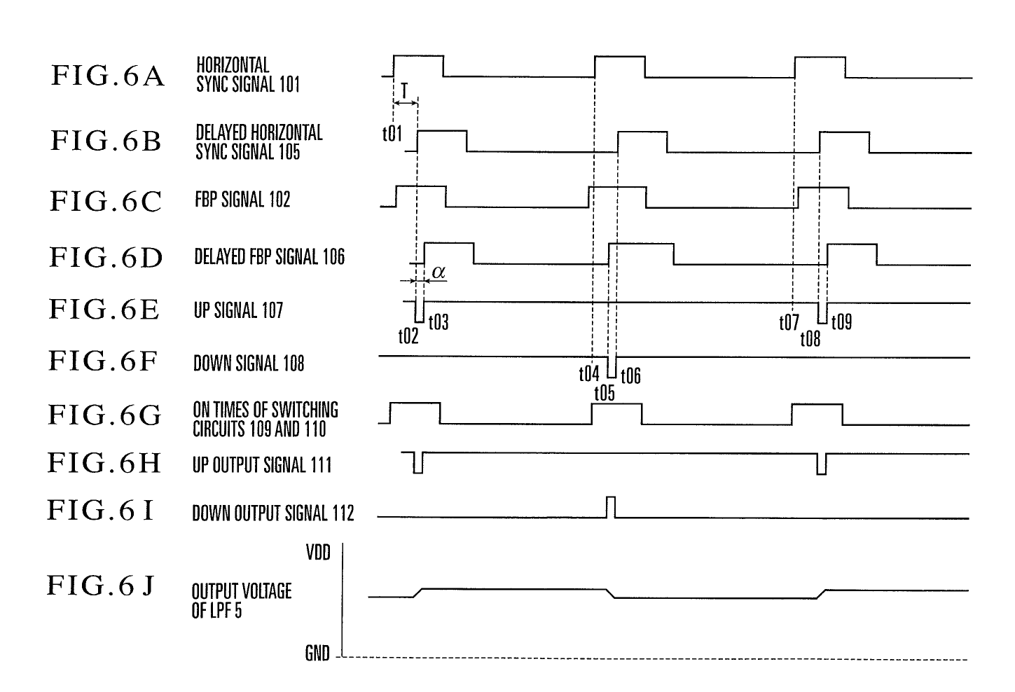

The operation of the PLL circuit in a case where the horizontal sync signal 101 (horizontal sync signal 1) is normally input will be described in detail next with reference to FIGS. 6A to 6J.

The phase comparator 2 compares the phase of the delayed horizontal sync signal 105 (FIG. 6B) that lags the horizontal sync signal 101 (FIG. 6A) by a delay amount T (t02−t01) of the delay circuit 103 with the phase of the delayed FBP signal 106 (FIG. 6D) that lags the FBP signal 102 (FIG. 6C) by a delay amount T (t03−t01) of the delay circuit 104, and outputs the UP signal 107 representing a phase difference α, as shown in FIG. 6E.

The phase comparator 2 compares the phase of the delayed horizontal sync signal 105 (FIG. 6B) that lags the horizontal sync signal 101 (FIG. 6A) by the delay amount (t05−t04) of the delay circuit 103 with the phase of the delayed FBP signal 106 (FIG. 6D) that lags the FBP signal 102 (FIG. 6C) by the delay amount (t06−t04) of the delay circuit 104, and outputs the DOWN signal 108 representing the phase difference. Note that on the timing charts, two signals are shown with a slight phase difference α to express jitter or the like.

When the input timing of the delayed FBP signal 106 leads the input timing of the delayed horizontal sync signal 105, as in the case where the horizontal sync signal 101 is input at time t04, the UP/DOWN signals 107 and 108 are output at timings earlier than the ON timings of the switching circuits 109 and 110. For this reason, the delay amount of the delay circuits 103 and 104 are set to be larger than expected jitter amounts.

Since the UP/DOWN signals 107 and 108 are output only during the ON times (FIG. 6G) of the switching circuits 109 and 110, the UP output signal 111 is output at the same timing as the UP signal 107, as shown in FIG. 6H. In addition, the DOWN output signal 112 is output as an inverted signal at the same timing as the DOWN signal 108, as shown in FIG. 6I.

When the UP output signal 111 and DOWN output signal 112 are input to the PMOS transistor 404 and NMOS transistor 405 of the charge pump 4, the voltage smoothed by the LPF 5 varies, as shown in FIG. 6J. More specifically, as the UP output signal 111 goes to L level, the PMOS transistor 404 is turned on. As a consequence, charge is supplied from VDD to raise the LPF voltage. As the DOWN output signal 112 changes to H level, charge is removed to GND to lower the output voltage of the LPF 5.

In a case other than the above case, since the transistors 404 and 405 are kept off, a high impedance is set, and the output voltage of the LPF 5 is held in the previous state. By changing the voltage of the LPF 5 in accordance with the phase difference α between the horizontal sync signal 101 and the FBP signal 102 in this manner, the VCO 6 is controlled to produce a phase-locked state.

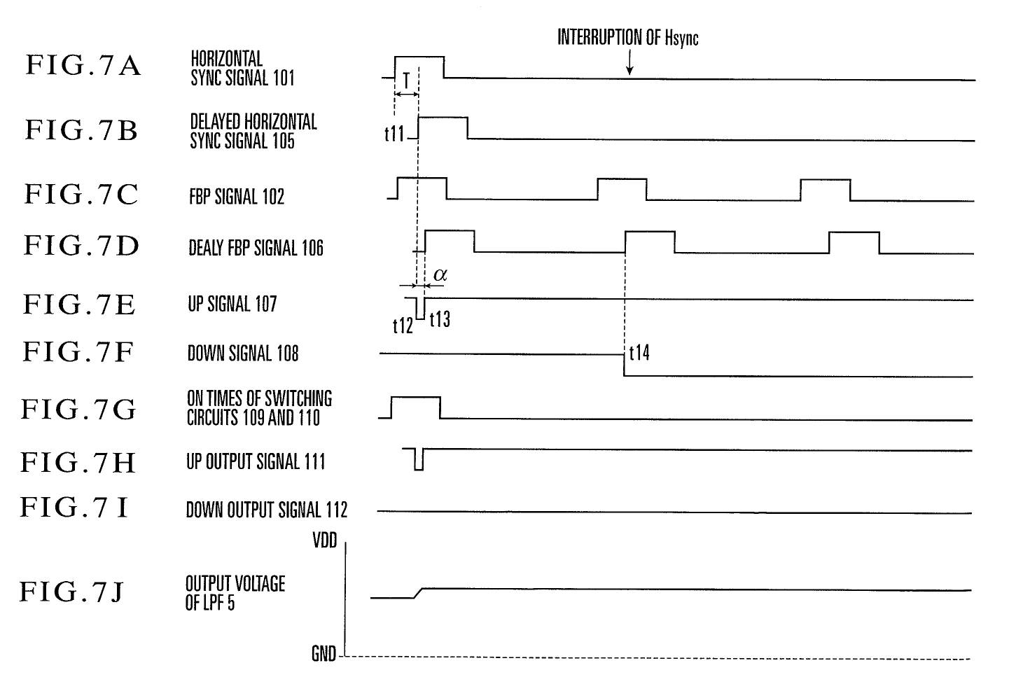

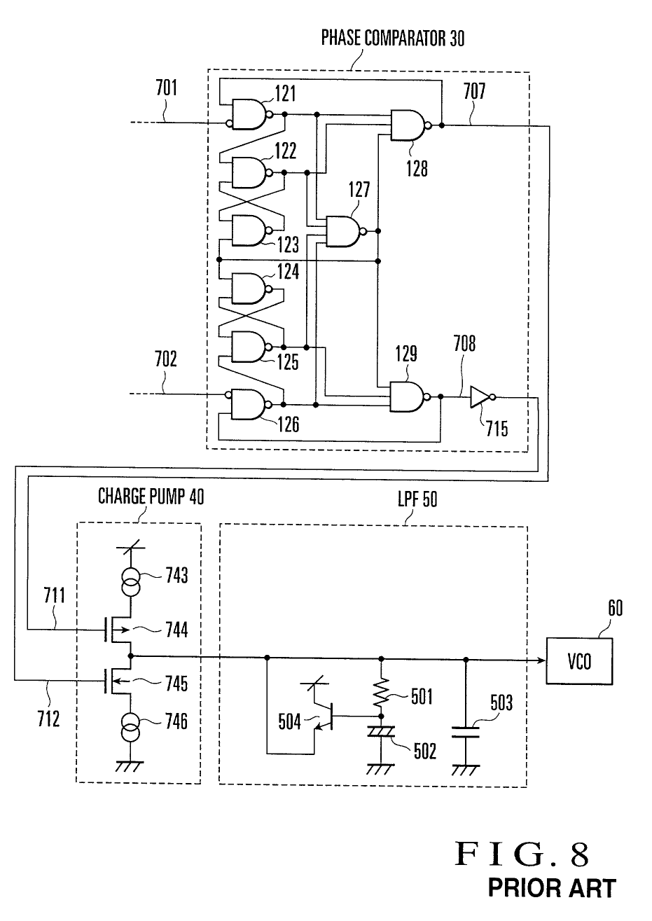

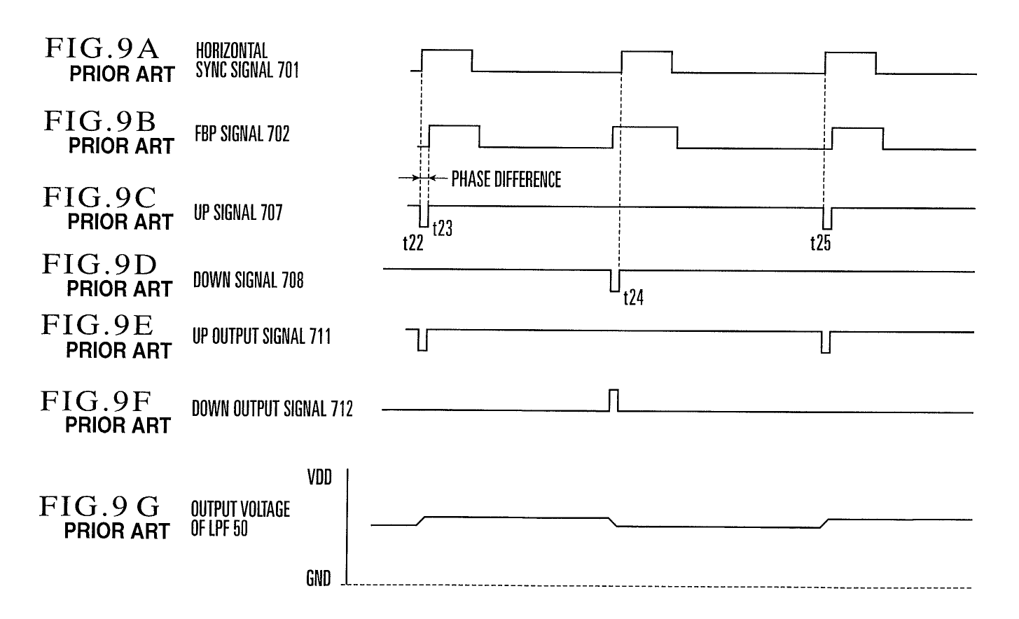

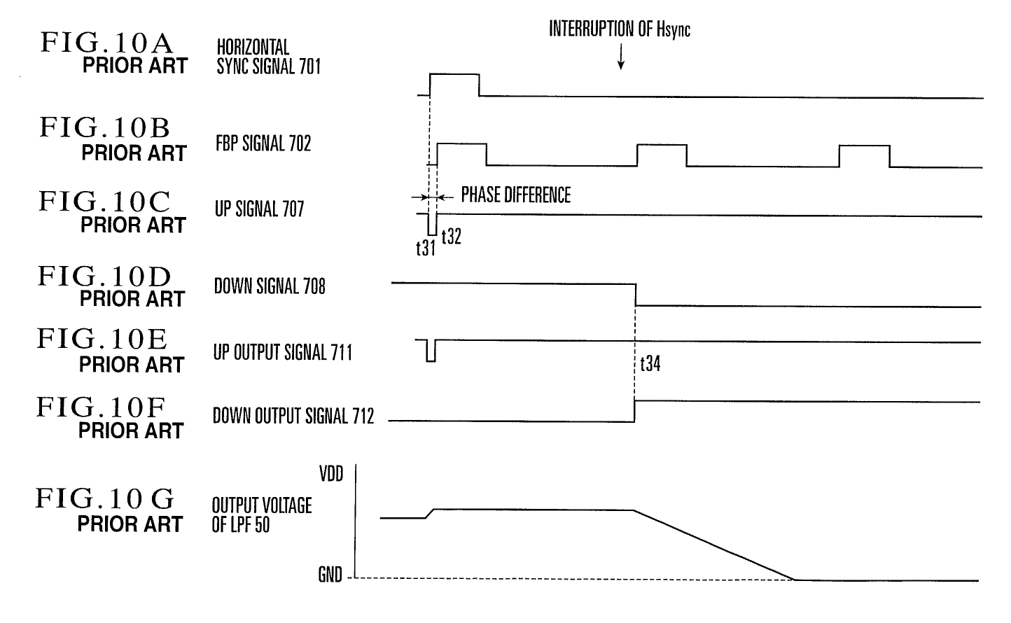

The operation of the PLL circuit in a case where the horizontal sync signal 101 (horizontal sync signal 1) is interrupted will be described in detail next with reference to FIGS. 7A to 7J.

When the horizontal sync signal 101 (FIG. 7A) is interrupted, the FBP signal 102 (FIG. 7C) and delayed FBP signal 106 (FIG. 7D) are input without any changes. For this reason, as shown in FIG. 7F, the DOWN signal 108 shifts to a state where a phase difference is produced, i.e., the L-level state, from the moment the delayed FBP signal 106 is input (t14) immediately after the horizontal sync signal 101 is interrupted. FIGS. 7B and 7E respectively show the delayed horizontal sync signal 105 and UP signal 107.

At time t14, since the horizontal sync signal 101 has already been interrupted and is not input, the switching circuits 109 and 110 are set in the OFF state, as shown in FIG. 7G. The switching signal 110 therefore outputs a GND-level signal regardless of the state of the DOWN signal 108. That is, the UP output signal 111 is kept at H level as shown in FIG. 7B, and the DOWN output signal 112 is kept at L level as shown in FIG. 7I.

No transistor of the charge pump 4 is therefore turned on, and an output from the LPF 5 keeps the control voltage signal 12 constant because no charging/discharging operation is performed, as shown in FIG. 7J. Since the control voltage 12 from the LPF 5 undergoes no variation, the VCO 6 outputs a constant oscillation frequency. As a consequence, the HOUT signal 8 holds the same frequency as that set immediately before the interruption of the horizontal sync signal 101.

Without the switching circuits 109 and 110, the NMOS transistor 405 is kept on, and hence the voltage of the LPF 5 abruptly drops. Therefore, the oscillation frequency of the VCO 6 decreases. As a result, the frequency of the HOUT signal abruptly decreases.

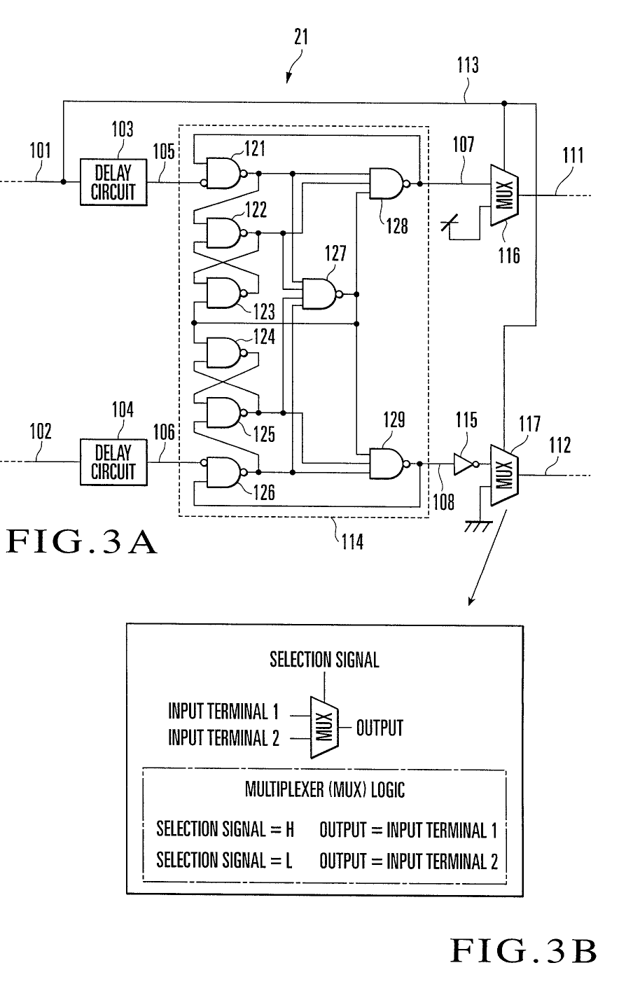

A PLL circuit according to the second embodiment of the present invention will be described next with reference to FIGS. 3A and 3B. This embodiment differs from the first embodiment in that the switching circuits 109 and 110 are implemented by multiplexers 116 and 117. Other arrangements are the same as those of the first embodiment, and hence a description thereof will be omitted.

Referring to FIG. 3A, a switching control signal 113 based on a horizontal sync signal 101 is input to the multiplexers 116 and 117. As shown in FIG. 3B, in each of the multiplexers 116 and 117, when a selection signal (switching control signal 113) is at H level, the signal input to an input terminal 1 is selected and output, whereas when the selection signal is at L level, the signal input to an input terminal 2 is selected and output.

In this embodiment, as in the first embodiment, the PLL circuit operates in accordance with the timing charts of FIGS. 6A to 6J and 7A to 7J. Even if, therefore, the horizontal sync signal 101 is interrupted, an HOUT signal 8 holds the same frequency as that set immediately before the interruption.

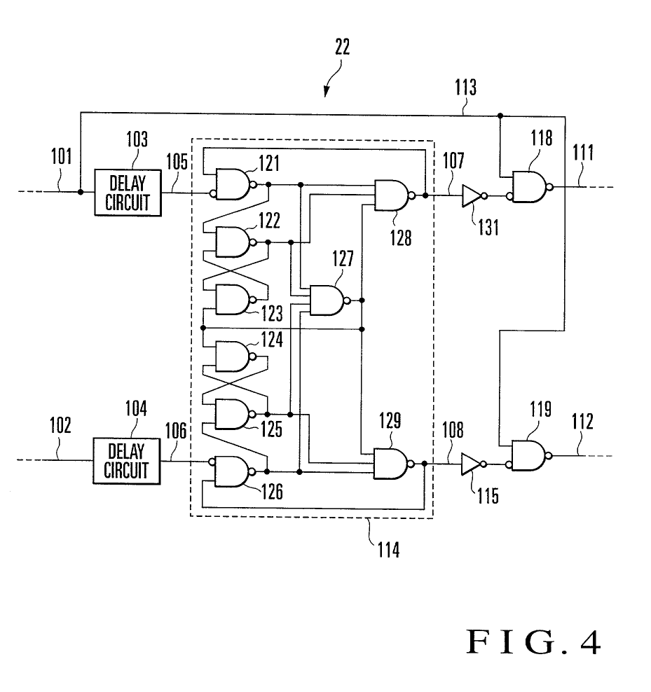

A PLL circuit according to the third embodiment of the present invention will be described next with reference to FIG. 4. This embodiment differs from the first embodiment in that the switching circuits 109 and 110 are respectively implemented by a NAND gate 118 and AND gate 119. Other arrangements are the same as those of the first embodiment, and hence a description thereof will be omitted.

Referring to FIG. 4, the NAND gate 118 receives two inputs, i.e., an UP signal 107 through an inverter 131 and a switching control signal 113, and outputs an UP output signal 111. The AND gate 119 receives two inputs, i.e., a DOWN signal 108 through an inverter 115 and the switching control signal 113, and outputs a DOWN output signal 112. Even if a horizontal sync signal 101 is interrupted, the PLL circuit according to this embodiment holds the HOUT signal 8 at the same frequency as that set immediately before the interruption of the horizontal sync signal 101, as in the first embodiment.

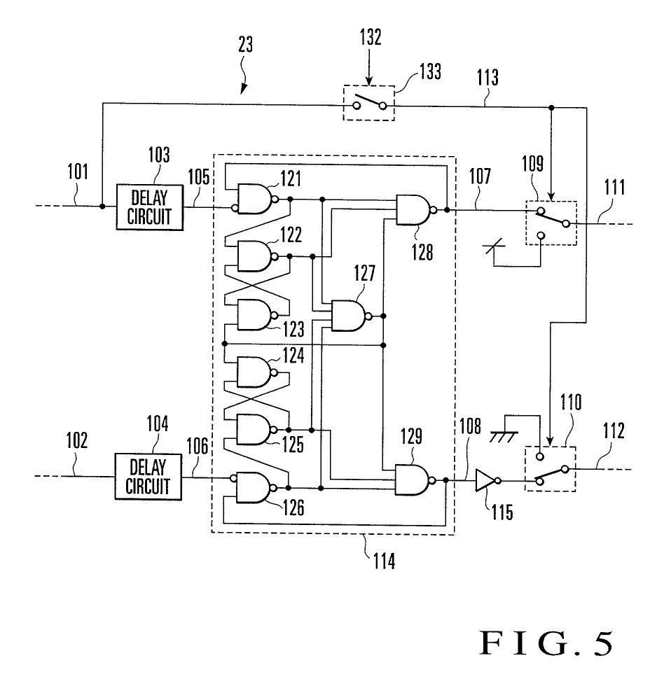

A PLL circuit according to the fourth embodiment of the present invention will be described next with reference to FIG. 5. This embodiment differs from the first embodiment in that a lock/unlock switching circuit 133 whose locked/unlocked state is controlled in accordance with a phase lock signal 132 is set in the route of a switching control signal 113. Other arrangements are the same as those of the first embodiment, and hence a description thereof will be omitted.

Referring to FIG. 5, when the lock/unlock switching circuit 133 is in the unlocked state, the route of the switching control signal 113 is interrupted to always keep switching circuits 109 and 110 in the ON state. When the lock/unlock switching circuit 133 is in the locked state, the route of the switching control signal 113 is formed, and switching operation is performed to output a phase difference output only during a horizontal sync signal interval, as in the first embodiment.

By outputting a phase difference output only during a horizontal sync signal interval, prolongation of a locking time can be prevented.

As has been described above, according to the present invention, even if a horizontal sync signal input is interrupted, since the HOUT signal is output at the oscillation frequency held at the same frequency as that set immediately before the interruption, the breakdown of a CRT monitor due to an abrupt decrease in frequency can be prevented.

In addition, since the above circuit can be realized by only adding delay circuits and switching circuits controlled by a horizontal sync signal, an increase in circuit size can be suppressed. Furthermore, by adding delay circuits having the same arrangement and same delay amount for a horizontal sync signal input and FBP input, worsening of jitter can be prevented because the characteristics change in accordance with the influences of external noise, power supply voltage variations, and the like.

What is claimed is:

1. A PLL circuit for a CRT monitor horizontal drive signal, comprising:
phase comparison means for comparing a phase of an input horizontal sync signal with a phase of an internal reference signal and outputting a phase difference signal;
charge pump means for outputting a charge pump signal in accordance with the phase difference signal from said phase comparison means;
filter means for converting the charge pump signal from said charge pump means into a voltage control signal;
a voltage controlled oscillator whose oscillation frequency is controlled in accordance with the voltage control signal output from said filter means;
frequency division means for frequency-dividing an output from said voltage controlled oscillator and outputting a CRT monitor horizontal drive signal phase-locked by a horizontal sync signal, the CRT monitor horizontal drive signal being used to generate the internal reference signal; and
switching means for outputting the phase difference signal from said phase comparison means to said charge pump means during an interval in which a horizontal sync signal is input, and outputting no phase difference signal from said phase comparison means during an interval in which no horizontal sync signal is input.

2. A circuit according to claim 1, wherein
said circuit further comprises a CRT drive circuit for performing CRT horizontal drive processing in accordance with an output from said frequency division means and generating a flyback pulse upon drive processing, and
said phase comparison means compares a phase of a horizontal sync signal with a phase of a flyback pulse output as an internal reference signal from said CRT drive circuit.

3. A circuit according to claim 1, further comprising:
first delay means for delaying the horizontal sync signal and outputting the signal to said phase comparison means; and
second delay means for delaying the internal reference signal and outputting the signal to said phase comparison means.

4. A circuit according to claim 3, wherein said first and second delay means have the same delay time.

5. A circuit according to claim 1, wherein said switching means comprises a pair of switches which are arranged in correspondence with UP and DOWN signals that represent a relationship between phases of two signals and are output from said phase comparison means, and perform switching operation in accordance with a horizontal sync signal.

6. A circuit according to claim 5, wherein
said charge pump means comprises a P-channel MOS transistor and N-channel MOS transistor which are connected in series to output a charge pump signal from a node to said filter means,
a gate of said P-channel MOS transistor is connected to an output terminal of one of said switches,
a gate of said N-channel MOS transistor is connected to an output terminal of the other switch,
one of said switches outputs an UP signal from said phase comparison means to the output terminal during an interval in which a phase comparison signal is input, and connects the output terminal to a power supply during an interval in which no phase comparison signal is input, and
the other switch outputs a DOWN signal from said phase comparison means to the output terminal during an interval in which a phase comparison signal is input, and connects the output terminal to ground during an interval in which no phase comparison signal is input.

7. A circuit according to claim 1, wherein said switching means comprises a pair of multiplexers which are arranged in correspondence with UP and DOWN signals represent a relationship between phases of two signals and are output from said phase comparison means, and perform selecting operation in accordance with a horizontal sync signal.

8. A circuit according to claim 1, wherein said switching means comprises a pair of gate circuits which are arranged in correspondence with UP and DOWN signals represent a relationship between phases of two signals and are output from said phase comparison means, and perform gating operation in accordance with a horizontal sync signal.

9. A circuit according to claim 1, wherein
said circuit further comprises lock/unlock switching means for ON/OFF-controlling said switching means using a horizontal sync signal in accordance with a phase clock signal, and
switching operation of said switching means is controlled by a horizontal sync signal.
